(19) United States
(12) Patent Application Publication
(10) Pub. No.: US 2024/0276870 A1
(43) Pub. Date: Aug. 15, 2024

(54) MONOLAYER ION-BLOCKING LAYERS FOR STABLE METAL HALIDE PEROVSKITE INTERFACES AND DEVICES

(71) Applicant: Alliance for Sustainable Energy, LLC, Golden, CO (US)

(72) Inventors: Jeffrey Lee BLACKBURN, Golden, CO (US); Matthew Peter HAUTZINGER, Golden, CO (US); Matthew Craig BEARD, Denver, CO (US); Joseph Matthew LUTHER, Boulder, CO (US)

(21) Appl. No.: 18/442,276

(22) Filed: Feb. 15, 2024

Related U.S. Application Data
(60) Provisional application No. 63/485,067, filed on Feb. 15, 2023.

(51) Int. Cl. H10K 85/50; H10K 30/20; H10K 30/40; H10K 71/12; H10K 71/50; H10K 85/30

(52) U.S. Cl. CPC H10K 85/50; H10K 30/20; H10K 30/40; H10K 71/12; H10K 71/50; H10K 85/30

(57) ABSTRACT

The present disclosure relates to a device that includes a first layer that includes a first perovskite that includes a first cation (A), a second cation (B), and first anion (X), a second layer that includes a second perovskite that includes a third cation (A′), a fourth cation (B′), and a second anion (X′), and a third layer that includes a two-dimensional (2D) material, where the third layer is physically positioned between the first layer and the second layer, and the third layer minimizes or eliminates the transfer of at least one of A, A′, B, B′, X, or X′ between the first layer and the second layer.

### CROSS-REFERENCE TO RELATED APPLICATIONS

This application claims priority from U.S. Provisional Patent Application No. 63/485,067 filed on Feb. 15, 2023, the contents of which are incorporated herein by reference in the entirety.

### CONTRACTUAL ORIGIN

This invention was made with government support under Contract No. DE-AC36-08GO28308 awarded by the Department of Energy. The government has certain rights in the invention.

### BACKGROUND

Interfaces between metal halide perovskites (MHPs) and other MHPs, or between MHPs and other materials/semiconductors, enable directed energy flow but labile ions often mix/homogenize across interfaces designed to have abrupt or graded interfacial energy landscapes. When MHPs are in direct contact with other MHPs or with other semiconductors, ions (especially halide ions/vacancies) can freely move across the interface, even at room temperature, disrupting the intended atomic stoichiometry (and concomitant electronic structure) of the interface. These MHP/MHP and MHP/semiconductor interfaces are ubiquitous and necessary components of a variety of opto-electronic technologies, including solar cells, tandem solar cells, light-emitting diodes, neuromorphic components (artificial synapses), and many other technologies. MHP device stability is also impacted by the ingress of ambient species like oxygen and water into the device. Thus, there remains a need for compositions, devices, and/or methods that can provide improved device stability.

### SUMMARY

An aspect of the present disclosure is a device that includes a first layer that includes a first perovskite that includes a first cation (A), a second cation (B), and first anion (X), a second layer that includes a second perovskite that includes a third cation (A′), a fourth cation (B′), and a second anion (X′), and a third layer that includes a two-dimensional (2D) material, where the third layer is physically positioned between the first layer and the second layer, and the third layer minimizes or eliminates the transfer of at least one of A, A′, B, B′, X, or X′ between the first layer and the second layer. In some embodiments of the present disclosure, the 2D material may include at least one of graphene or hexagonal boron nitride, phosphorene, silicene, and/or a transition metal dichalcogenide. In some embodiments of the present disclosure, the transition metal dichalcogenide may include at least one of MoS₂, MoSe₂, MoTe₂, WS₂, and/or WSe₂. In some embodiments of the present disclosure, the third layer may be a monolayer of the 2D material.

In some embodiments of the present disclosure, the first perovskite may include at least one of a one-dimensional (1D) structure, a 2D structure, and/or a three-dimensional (3D) structure. In some embodiments of the present disclosure, each of A and A′ may independently include at least one of methylammonium (MA), formamidinium (FA), dimethylammonium (DMA), ethylammonium, acetamidinium, guanidinium, methylenediammonium, propylammonium, butylammonium, octylammonium, dodecylammonium, phenethylammonium, and/or cesium. In some embodiments of the present disclosure, the third layer may minimize the transfer of at least one of A or A′ from the first layer to the second layer and/or the transfer of at least one of A or A′ from the second layer to the first layer.

In some embodiments of the present disclosure, each of B and B′ may independently include at least one of a 2+ cation and/or a 3+ cation. In some embodiments of the present disclosure, each of B and B′ may independently include at least one of tin, lead, germanium, manganese, bismuth, silver, antimony, indium, copper, and/or europium. In some embodiments of the present disclosure, the third layer may minimize the transfer of at least one of B or B′ from the first layer to the second layer and/or the transfer of at least one of B or B′ from the second layer to the first layer.

In some embodiments of the present disclosure, each of X and X′ may independently include at least one of a halide, acetate, and/or a pseudohalide. In some embodiments of the present disclosure, the pseudohalide may include at least one of cyanide, cyaphide, isocyanide, hydroxide bioxide, hydrosulfide bisulfide, cyanate, isocyanate, fulminate, thiocyanate, isothiocyanate, hypothiocyanite, nitrite, tetracarbonylcobalt, trinitromethanide, and/or tricyanomethanide. In some embodiments of the present disclosure, each of X and X′ may independently comprise at least one of fluoride, iodide, chloride, or bromide.

In some embodiments of the present disclosure, at least a portion of X of the first perovskite may be different than X′ of the second perovskite. In some embodiments of the present disclosure, the third layer may minimize the transfer of at least one of X or X′ from the first layer to the second layer and/or the transfer of at least one of X or X′ from the second layer to the first layer. In some embodiments of the present disclosure, the first perovskite may include ABI₃, and the second perovskite may include A′B′Br₃. In some embodiments of the present disclosure, the third layer may minimize the transfer of at least one of iodide from the first layer to the second layer and/or the transfer of bromide from the second layer to the first layer.

In some embodiments of the present disclosure, at least a portion of X of the first perovskite may be the same as X′ of the second perovskite, and X may be present in the first perovskite at a first stoichiometry that is different than a second stoichiometry of X′ in the second perovskite. In some embodiments of the present disclosure, the first perovskite may include AB(I₁₋ᵥBrᵥ)₃, the second perovskite may include A′B′(I_{1-w}Br_{w})₃, 0<v<1, 0<w<1, and w≠v. In some embodiments of the present disclosure, the third layer may minimize the transfer of at least one of iodide or bromide from the first layer to the second layer and/or the transfer of at least one of iodide or bromide from the second layer to the first layer.

### BRIEF DESCRIPTION OF DRAWINGS

Some embodiments are illustrated in referenced figures of the drawings. It is intended that the embodiments and figures disclosed herein are to be considered illustrative rather than limiting.

FIGS. 1A and 1B illustrate a perovskite in a corner-sharing, cubic phase arrangement, according to some embodiments of the present disclosure.

FIG. 2A illustrates three possible corner-sharing phases for perovskites, Panel A cubic phase (i.e., α-ABX₃), Panel B a tetragonal crystalline phase (i.e., β-ABX₃), and Panel C an orthorhombic crystalline phase (i.e., γ-ABX₃), according to some embodiments of the present disclosure.

FIG. 2B illustrates a perovskite in one of the three possible phases, the cubic phase (i.e., α-phase), compared to two non-perovskite phases (i.e., non-corner sharing), according to some embodiments of the present disclosure.16A

FIG. 3 illustrates 2D, 1D, and 0D perovskite-like structures, in Panels A, B, and C, respectively, according to some embodiments of the present disclosure.

FIG. 4A illustrates (Panel A) a schematic of the single-layer graphene (SLG) transfer method, according to some embodiments of the present disclosure.

FIG. 4B illustrates a time-of-flight secondary ion mass spectrometry (TOF-SIMS) 3D rendering (25×25 um) of the (Panel A) CsPbBr₃/SLG/CsPbI₃ heterostructure (depth ˜650 nm) and (Panel B) a control without the SLG, i.e., direct contacting of the perovskite layers (depth ˜200 nm), according to some embodiments of the present disclosure. Panel C illustrates a cross section SEM image of the heterostructure, according to some embodiments of the present disclosure.

FIG. 5 illustrates TOF-SIMS of individual ions and overlay of the (Panel A) CsPbBr₃/SLG/CsPbI₃ heterostructure and (Panel B) control CsPbBr₃/CsPbI₃ (i.e., no graphene), according to some embodiments of the present disclosure. Each data set is 25×25 μm² in area and measurement depth of (Panel A) ˜650 nm and (Panel B) ˜200 nm. The graphene heterostructure in (Panel A) was intentionally made thicker to enhance the resolution. Iodide rich nanocrystals (NCs) on the surface or locally thicker parts of the film take longer to sputter through and thus a projected deeper into the film as it is profiled, causing artificially deep “spikes’ in the tomography data.

FIGS. 6A and 6B illustrate TOF-SIMS line profiles of (FIG. 6A) the CsPbBr₃/SLG/CsPbI₃ heterostructure and (FIG. 6B) of the control CsPbBr₃/CsPbI₃ (i.e., no graphene), according to some embodiments of the present disclosure.

FIG. 7 illustrates scanning electron micrograph (SEM) of the (Panel A) CsPbBr₃ NC film, (Panel B) CsPbBr₃/SLG, and (Panel C) CsPbBr₃/SLG/CsPbI₃ samples, according to some embodiments of the present disclosure. Images (Panel D) and (Panel E) show CsPbBr₃/SLG samples specifically made for imaging, where only half the CsPbBr₃ was covered in SLG allowing images of the edges of the graphene.

FIG. 8 illustrates images of atomic force microscopy (AFM) topography maps of the (Panel A) CsPbBr₃ NC film (root-mean square (RMS) roughness=3.0564 nm) and the (Panel B) CsPbBr₃/SLG (RMS roughness=2.4345 nm), according to some embodiments of the present disclosure.

FIG. 9 illustrates photographs under ultraviolet (UV) illumination of the backside of the (Panel A) CsPbBr₃/graphene/CsPbI₃ heterostructure and (Panel B) sequentially deposited CsPbBr₃/CsPbI₃ film i.e. homogenized halide distribution, according to some embodiments of the present disclosure.

FIG. 10 illustrates (Panel A) absorbance and PL spectra of control films of CsPbBr₃, CsPbI₃, CsPbBr₃/CsPbI₃ deposited sequentially without the SLG (control), and of the heterostructure CsPbBr₃/SLG/CsPbI₃ (hetero.) and (Panel B) PL of the CsPbBr₃/SLG/CsPbI₃ heterostructure over the course of 30 days, whereas the control sample is completely mixed almost instantaneously, according to some embodiments of the present disclosure. Different dashed lines denote separate scans to probe the full wavelength range.

FIG. 11 illustrates ultraviolet photoelectron spectroscopy (UPS) spectra of the materials, according to some embodiments of the present disclosure. CPI=CsPbI₃ NC film, CPB=CsPbBr₃ NC film, while CPX_SLG denotes samples with graphene present. (CPI: 4.62 eV, SLG_CPI: 4.50 eV, CPB: 4.76 eV, CPB_SLG: 4.63 eV, SLG: 4.51 eV)

FIG. 12 illustrates (Panel A) work function, versus vacuum (0 eV), as determined by UPS of the CsPbI₃ and CsPbBr₃ control samples and with the SLG showing the slight raising of the work function with SLG incorporation, according to some embodiments of the present disclosure. The work function of the SLG is also shown. Density functional theory (DFT) band structure calculations of SLG incorporated with (Panel B) CsPbI₃ and (Panel C) CsPbBr₃.

FIG. 13 illustrates a comparison of experimental and DFT calculated bandgaps for several structures, according to some embodiments of the present disclosure.

FIG. 14 illustrates first DFT relaxed slab structures with graphene and (Panel A) CsPbI₃ and (Panel B) CsPbBr₃ along with overhead views of the graphene/perovskite lattice combinations used to form the (Panel C) CsPbI₃ and (Panel D) CsPbBr₃ supercells, according to some embodiments of the present disclosure.

FIG. 15 illustrates second DFT relaxed slab structures with graphene and (Panel A) CsPbI₃ and (Panel B) CsPbBr₃ along with overhead views of the graphene/perovskite lattice combinations used to form the (Panel C) CsPbI₃ and (Panel D) CsPbBr₃ supercells, according to some embodiments of the present disclosure.

FIG. 16 illustrates DFT band structure and density of states for bulk (A) CsPbI₃ and (B) CsPbBr₃ along with corresponding unit cell (C and E) and Brillouin zone showing the chosen k-path (D and F), according to some embodiments of the present disclosure.

FIG. 17 illustrates transient absorbance spectroscopy of the CsPbI₃(A) and CsPbBr₃(B) control samples (with SLG integrated) in contrast to the CsPbBr₃/SLG/CsPbI₃ heterostructures, according to some embodiments of the present disclosure. The curves are the models for the single layer and heterostructure, where the CsPbBr₃ has shorter lifetimes while the CsPbI₃ has longer lifetimes attributed to energy transfer across the SLG interfacial layer.

FIGS. 18A-18C illustrate electroluminescence of the ITO/PEDOT:PSS/CsPbBr₃/SLG/CsPbI₃/PFN-DOF/Au LED, according to some embodiments of the present disclosure.

### REFERENCE NUMBERS

100 . . . perovskite
110 . . . A-cation
120 . . . B-cation
130 . . . X-anion
400 . . . method
410 . . . first depositing
412 . . . first perovskite layer
414 . . . substrate
416 . . . first composite structure
420 . . . preparing
422 . . . transfer layer
424 . . . blocking layer
426 . . . second composite structure
430 . . . applying
435 . . . intermediate stack
440 . . . curing
450 . . . removing
460 . . . second depositing
465 . . . second perovskite layer
470 . . . final device stack DETAILED DESCRIPTION

The present disclosure relates to the mitigation of ion diffusion, migration, and mixing across metal halide perovskite interfaces by utilizing monolayer interfacial ion-blocking monolayers of graphene and/or hexagonal boron nitride (h-BN) that simultaneously enable through-layer photoinduced charge and/or energy transfer. In some embodiments of the present disclosure, an ion-blocking layer constructed of a single layer of graphene (SLG) was deposited between metal-halide perovskite layers. This demonstrated that the SLG effectively blocks anion diffusion in a CsPbBr₃/SLG/CsPbI₃ heterostructure. Spatially resolved elemental analysis and spectroscopic measurements demonstrate the halides do not diffuse across the interface, whereas control samples without the SLG show rapid homogenization of the halides and loss of sharply defined interfaces. Although a blocking layer was specifically demonstrated for anions, blocking layers as described herein may be utilized to minimize or eliminate the transfer of any ions present in perovskites, including A-site (cations such as Cs⁺, alkyl ammonium cations, formamidinium, etc.) and B-site cations (cations such as Pb²⁺, Sn²⁺, etc.). Similarly, although SLGs were specifically demonstrated as effective blocking layers, other two-dimensional (2D) materials may also be utilized as blocking layers to minimize or prevent the transfer of ions between neighboring layers. Other examples of 2D materials that fall within the scope of the present disclosure include bi-layer 2D materials and multi-layer 2D materials such as bilayer graphene and hexagonal boron nitride.

Ultraviolet photoelectron spectroscopy, DFT calculations, and transient absorbance spectroscopy indicate the SLG has little electronic impact on the individual semiconductors. In the CsPbBr₃/SLG/CsPbI₃, a type I band alignment is present that supports transfer of photogenerated carriers across the heterointerface. Light-emitting diodes (LEDs) show electroluminescence from both the CsPbBr₃ and CsPbI₃ layers with no evidence of ion-diffusion during operation. This approach provides opportunities to design novel all-perovskite heterostructures to facilitate the control of charge and light in technological applications.

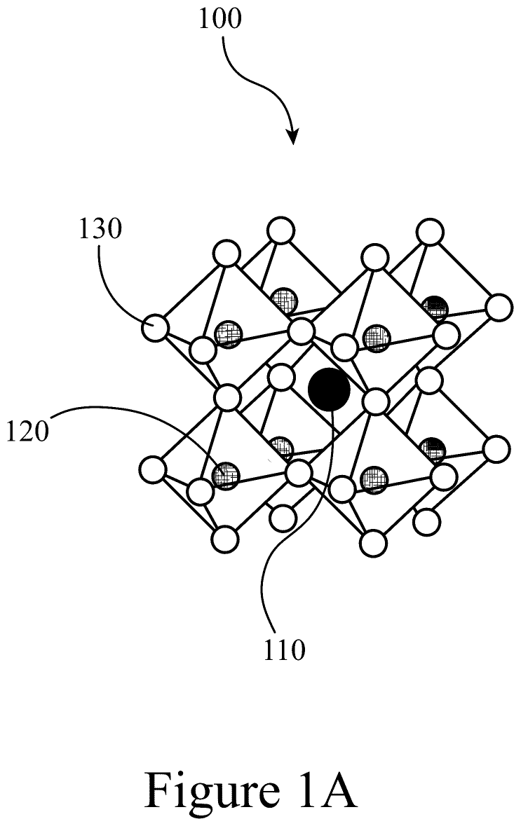

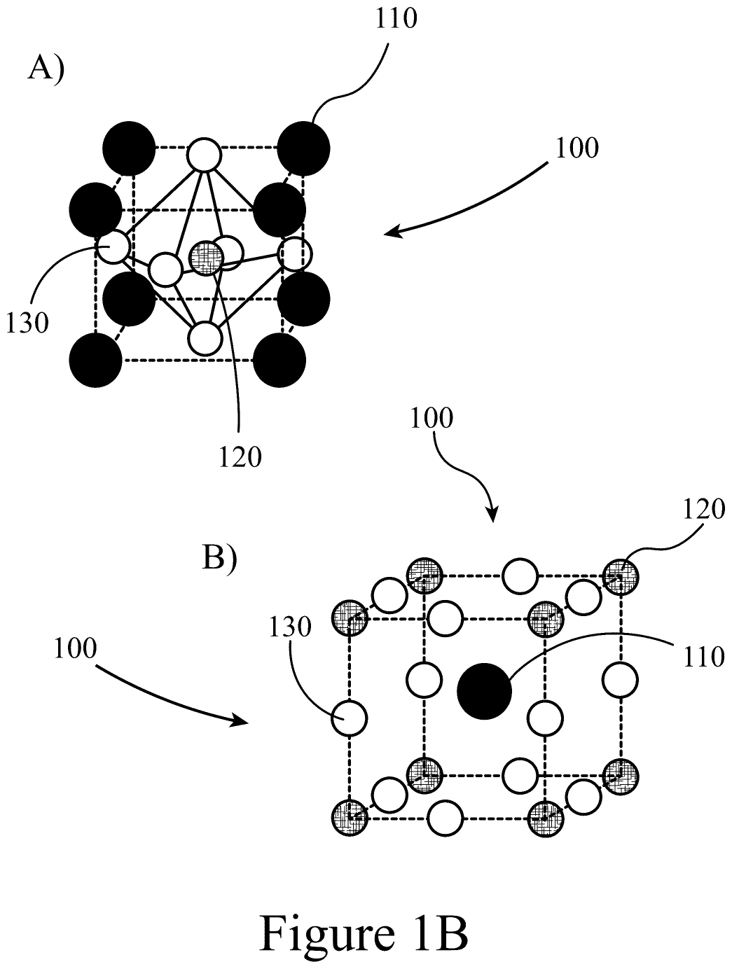

In general, the term “perovskite” refers to compositions having a network of corner-sharing BX₆ octahedra resulting in the general stoichiometry of ABX₃. FIGS. 1A and 1B illustrate that perovskites 100, for example metal halide perovskites, may organize into a three-dimensional (3D) cubic crystalline structures (i.e., α-phase or α-ABX₃) constructed of a plurality of corner-sharing BX₆ octahedra. In the general stoichiometry for a perovskite, ABX₃, X (130) is an anion and A (110) and B (120) are cations, typically of different sizes. FIG. 1A illustrates that a perovskite 100 having an α-phase structure may be further characterized by eight BX₆ octahedra surrounding a central A-cation 110, where each octahedra is formed by six X-anions 130 surrounding a central B-cation 120 and each of the octahedra are linked together by “corner-sharing” of anions, X (130).

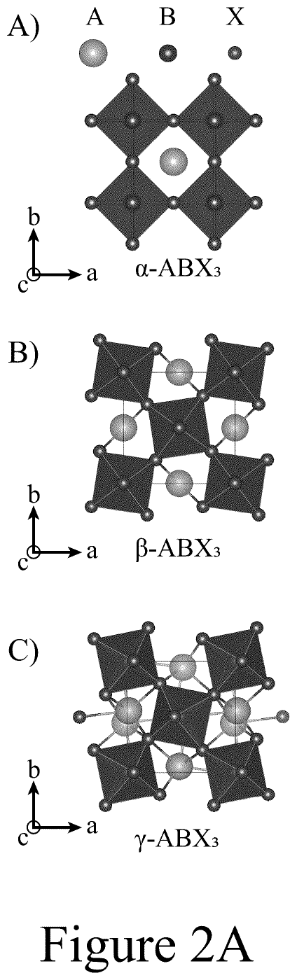

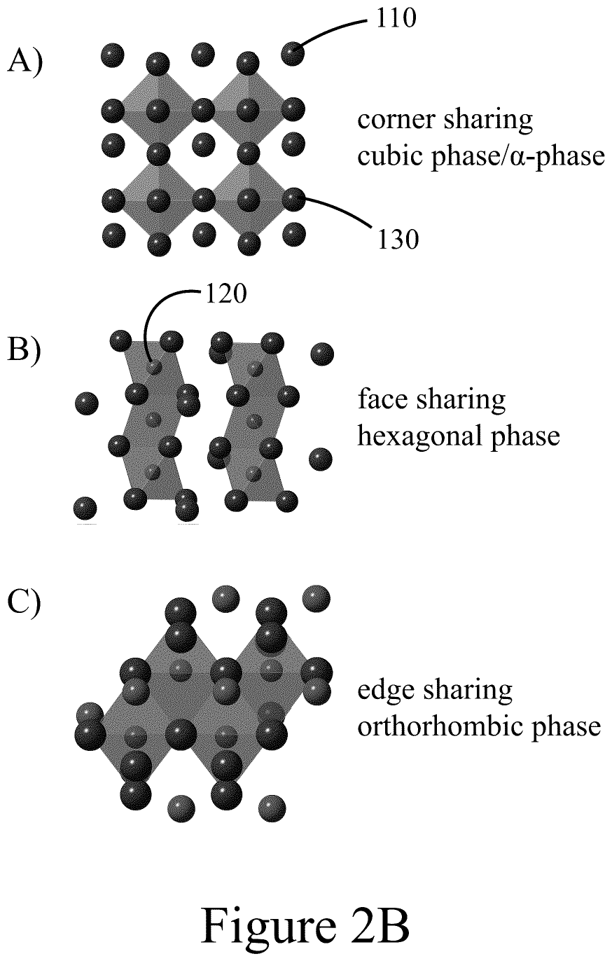

Panel A of FIG. 1B provides another visualization of a perovskite 100 in the α-phase, also referred to as the cubic phase. This is because, as shown in FIG. 1B, a perovskite in the a-phase may be visualized as a cubic unit cell, where a B-cation 120 is positioned at the center of the cube, an A-cation 110 is positioned at each corner of the cube, and an X-anion 130 is face-centered on each face of the cube. Panel B of FIG. 1B provides another visualization of the cubic unit cell of an α-phase perovskite, where a B-cation 120 resides at the eight corners of a cube, while an A-cation 110 is located at the center of the cube and with 12 X-anions 130 centrally located between B-cations 120 along each edge of the unit cell. For both unit cells illustrated in FIG. 1B, the A-cations 110, the B-cations 120, and the X-anions 130 balance to the general formula ABX₃ of a perovskite, after accounting for the fractions of each atom shared with neighboring unit cells. For example, referring to Panel A of FIG. 1B, the single B-cation 120 atom is not shared with any of the neighboring unit cells. However, each of the six X-anions 130 is shared between two unit cells, and each of the eight A-cations 110 is shared between eight unit cells. So, for the unit cell shown in Panel A of FIG. 1B, the stoichiometry simplifies to B=1, A=8*0.125=1, and X=6*0.5=3, or ABX₃. Similarly, referring again to Panel B of FIG. 1B, since the A-cation is centrally positioned, it is not shared with any of the unit cells neighbors. However, each of the 12 X-anions 130 is shared between four neighboring unit cells, and each of the eight B-cations 120 is shared between eight neighboring unit cells, resulting in A=1, B=8*0.125=1, and X=12*0.25=3, or ABX₃. Referring again to Panel B of FIG. 1B, the X-anions 130 and the B-cations 120 of a perovskite in the α-phase are aligned along an axis; e.g., where the angle at the X-anion 130 between two neighboring B-cations 120 is exactly 180 degrees, referred to herein as the tilt angle. However, as shown in FIG. 2A, a perovskite 100 may assume other corner-sharing crystalline phases having tilt angles not equal to 180 degrees.

FIG. 2A illustrates that a perovskite can assume other crystalline forms while still maintaining the criteria of an ABX₃ stoichiometry with neighboring BX₆ octahedra maintaining X anion (130) corner-sharing. Thus, in addition to α-ABX₃ perovskites (in the cubic phase) having a tilt angle of 180 degrees, shown in Panel A of FIG. 2A, a perovskite may also assume a tetragonal crystalline phase (i.e., β-ABX₃) (see Panel B of FIG. 2A) and/or an orthorhombic crystalline phase (i.e., γ-ABX₃) (see Panel C of FIG. 2A), where the adjacent octahedra are tilted relative to the reference axes a, b, and c.

FIG. 2B illustrates that the elements used to construct a perovskite, as described above, A-cations 110, B-cations 120, and X-anions 130, may result in 3D non-perovskite structures; i.e., structures where neighboring BX₆ octahedra are not X-anion 130 corner-sharing and/or do not have a unit structure that simplifies to the ABX₃ stoichiometry. Referring to FIG. 2B, Panel A illustrates a perovskite in the cubic phase, i.e., α-ABX₃, compared to a non-perovskite structure constructed of face-sharing BX₆ octahedra resulting in a hexagonal crystalline structure (see Panel B of FIG. 2B) and a non-perovskite structure constructed of edge-sharing BX₆ octahedra resulting in an orthorhombic crystalline structure (see Panel C of FIG. 2B).

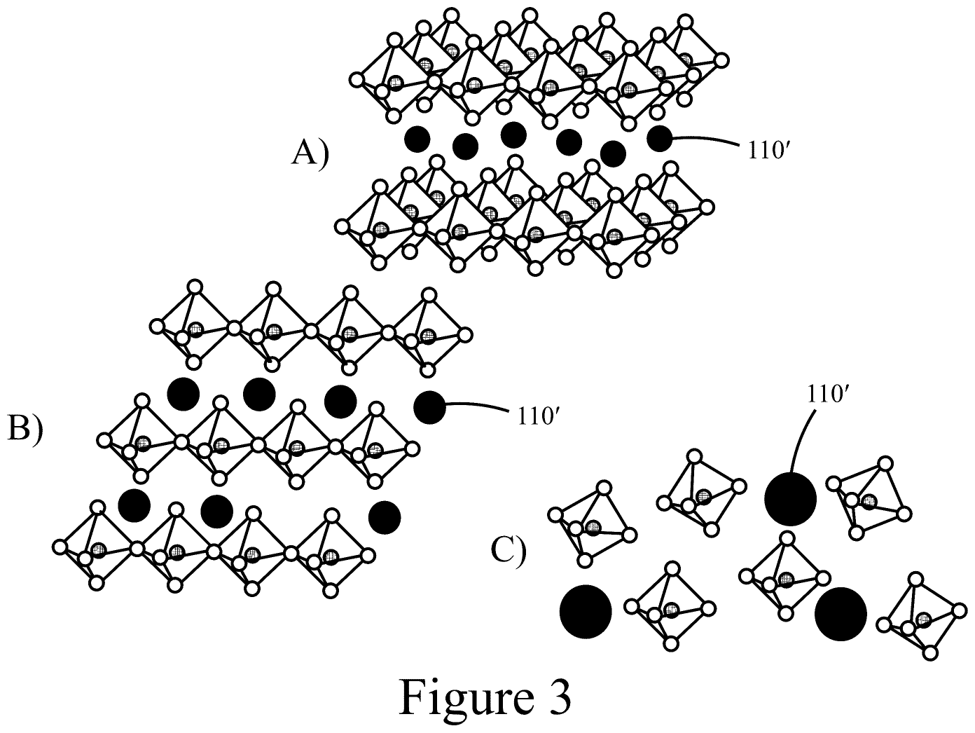

Further, referring now to FIG. 3, the elements used to construct a perovskite, as described above, A-cations 110, B-cations 120, and X-anions 130, may result in non-3D (i.e., lower dimensional structures) perovskite-like structures such as two-dimensional (2D) structures, one-dimensional (1D) structures, and/or zero-dimensional (0D) structures. As shown in FIG. 3, such lower dimensional, perovskite-like structures still include the BX₆ octahedra, and depending on the dimensionality, e.g., 2D or 1D, may still maintain a degree of X-anion corner-sharing. However, as shown in FIG. 3, the X-anion 130 corner-sharing connectivity of neighboring octahedra of such lower dimensional structures, i.e., 2D, 1D, and 0D, is disrupted by intervening A-cations 110. Such a disruption of the neighboring octahedra, can be achieved by, among other things, varying the size of the intervening A-cations 110.

Referring to Panel A of FIG. 3, a 3D perovskite may be transformed to a 2D perovskite-like structure, 1D perovskite-like structure, and/or GD perovskite-like structure. Where the degree of X-anion 130 corner sharing decreases and the stoichiometry changes according to the formula (A′)ₘ(A)ₙ₋₁BₙX₃ₙ₊₁, where monovalent (m=2) or divalent (m=1) A′ cations 110′ can intercalate between the X-anions of 2D perovskite-like sheets. Referring to Panel B of FIG. 3, 1D perovskite-like structures are constructed by BX₆ octahedral chained segments spatially isolated from each other by surrounding bulky organic A′-cations 110′, leading to bulk assemblies of paralleled octahedral chains. Referring to Panel C of FIG. 3, typically, the 0D perovskite-like structures are constructed of isolated inorganic octahedral clusters and surrounded by small A′-cations 110′, which may be connected via hydrogen bonding. In general, as n approaches infinity the structure is a pure 3D perovskite and when n is equal to 1, the structure is a pure 2D perovskite-like structure. More specifically, when n is greater than 10 the structure is considered to be essentially a 3D perovskite material and when n is between 1 and 5, inclusively, the structure is considered substantially a 2D perovskite-like material. For simplification, as used herein the term “perovskite” will refer to each of the structures illustrated in FIGS. 1A through 3, unless specified otherwise.

In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁_₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH₃⁺), ethylammonium (CH₃CH₂NH₃⁺), propylammonium (CH₃CH₂ CH₂NH₃⁺), butylammonium (CH₃CH₂ CH₂ CH₂NH₃⁺), formamidinium (NH₂CH═NH₂⁺), hydrazinium, acetylammonium, dimethylammonium, imidazolium, guanidinium, benzylammonium, phenethylammonium, butylammonium and/or any other suitable nitrogen-containing or organic compound. In other examples, an A-cation 110 may include an alkylamine. Thus, an A-cation 110 may include an organic component with one or more amine groups. For example, an A-cation 110 may be an alkyl diamine halide such as formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C). Additional examples of alkyl groups include n-heptyl (C₇), n-octyl (C₈) and the like.

Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g., fluorine, chlorine, bromine, iodine and/or astatine. In some cases, the perovskite halide may include more than one X-anion 130, for example pairs of halogens; chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cation 120, and X-anion 130 may be selected within the general formula of ABX₃ to produce a wide variety of perovskites 100, including, for example, methylammonium lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities; e.g., x is not equal to 1, 2, or 3. In addition, perovskite halides, like other organic-inorganic perovskites, can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens (e.g., at least one of I, Br, Cl, and/or F), thiocyanate, and/or sulfur. Any combination is possible provided that the charges balance.

For example, a perovskite having the basic crystal structure illustrated in FIGS. 1A and 1B, in at least one of a cubic, orthorhombic, and/or tetragonal structure, may have other compositions resulting from the combination of the cations having various valence states in addition to the 2+ state and/or 1+ state described above for lead and alkyl ammonium cations; e.g., compositions other than AB²⁺X₃ (where A is one or more cations, or for a mixed perovskite where A is two or more cations). Thus, the methods described herein may be utilized to create novel mixed cation materials having the composition of a double perovskite (elpasolites), A₂B¹⁺B³⁺X₆, with an example of such a composition being Cs₂BiAgCl₆ and Cs₂CuBiI₆. Another example of a composition covered within the scope of the present disclosure is described by A₂B⁴⁺X₆, for example Cs₂PbI₆ and Cs₂SnI₆. Yet another example is described by A₃B₂₃+X₉, for example Cs₃Sb₂I₉. For each of these examples, A is one or more cations, or for a mixed perovskite, A is two or more cations.

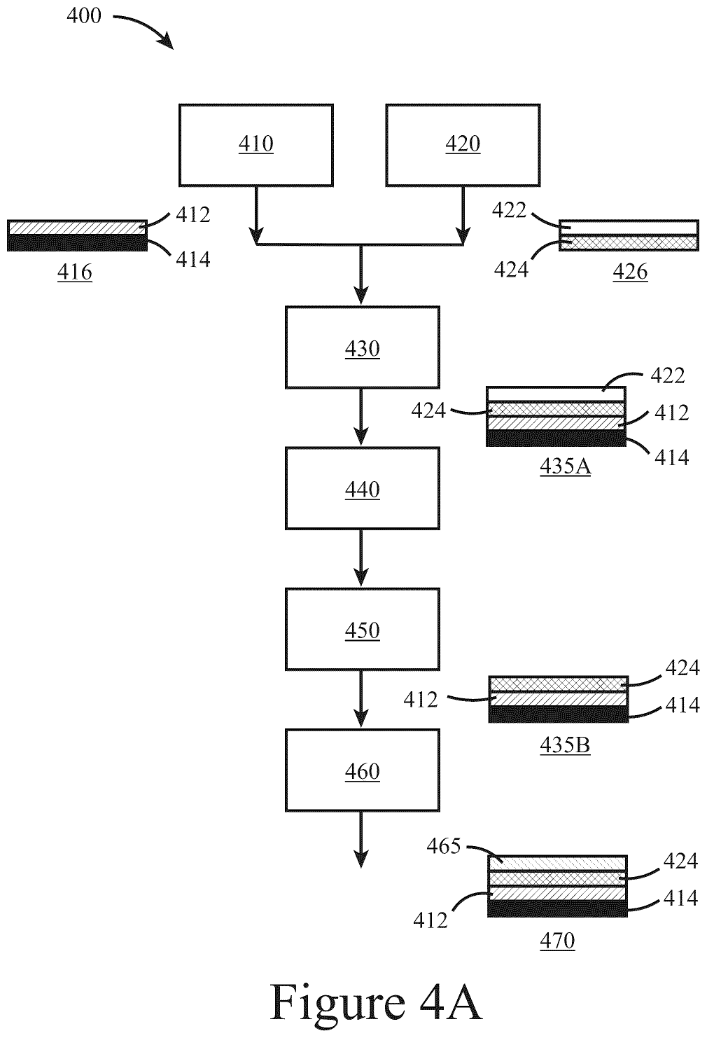

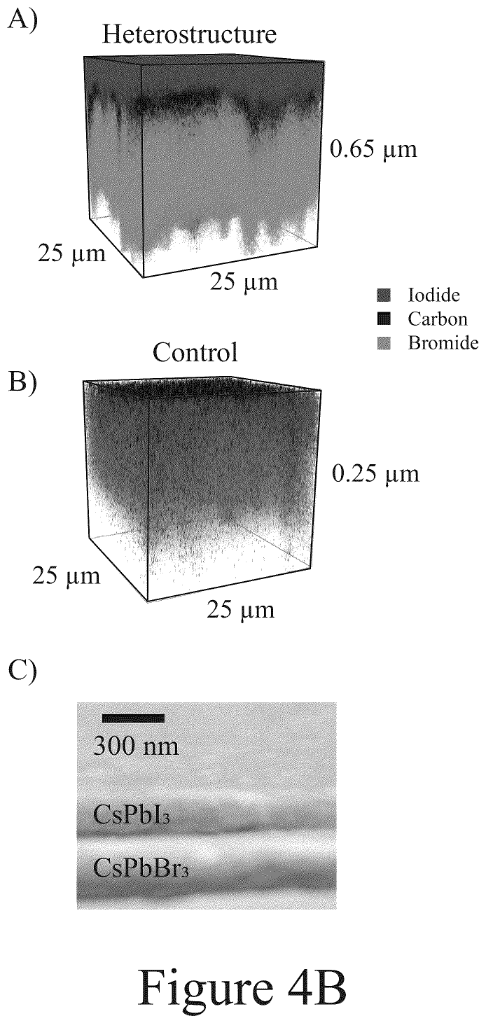

To produce all perovskite/perovskite heterostructures with SLG (also referred to herein as a “graphene layer”) integrated as an ion diffusion blocking layer, a solvent free transfer process was utilized to form a stable graphene layer. CsPbI₃/SLG/CsPbBr₃ heterostructures were synthesized. However, the process described herein can be applied to other perovskite compositions, crystalline structures, etc., and the CsPbI₃/SLG/CsPbBr₃ embodiment is provided as an example and is not intended to be limiting. FIG. 4A illustrates a method 400 for making a final device stack 470 that includes a blocking layer 424, e.g., a graphene layer, positioned between a first perovskite layer 412 and a second perovskite layer 465, such that the blocking layer 424 minimizes and/or eliminates the transfer of anions and cations between the two perovskite layers (412 and 465), according to some embodiments of the present disclosure.

As illustrated in FIG. 4A, a method 400 for making a perovskite/SLG/perovskite composite device stack may begin with a first depositing 410 of a first perovskite layer 412 onto a substrate 414, creating a first composite structure 416. A first depositing 410 may be achieved using one or more vapor deposition methods (e.g., chemical vapor phase deposition) and/or liquid-phase deposition methods (e.g., blade-coating, curtain-coating, dip-coating, spin-coating, etc.). In some embodiments of the present disclosure, e.g., liquid-phase depositing, a first depositing 410 step may be followed by a treating step (not shown), e.g., heating a first perovskite layer 412, contacting a first perovskite layer 412 with a solvent, and/or contacting a first perovskite layer 412 with a gas stream. Among other things, such a treating step may assist a first perovskite layer 412 with reaching and/or approaching complete crystallization.

Referring again to FIG. 4A, a method 400 may also include a preparing 420 of a blocking layer 424 for the applying 430 of the blocking layer 424 to the first perovskite layer 412. For example, an applying 430 step may include contacting a blocking layer 424 with a transfer layer 422, e.g., a solid layer with an adhesive layer applied to a surface of the solid layer, such that the blocking layer 424 adheres to the transfer layer 422, resulting in a second composite structure 426 (blocking layer 424/transfer layer 422). In some embodiments of the present disclosure, a transfer layer 422 may be a heat release transfer tape or a UV curing tape. The blocking layer 424 may then be placed in direct contact with the first perovskite layer 412 (positioned on a substrate 414 as part of a first composite structure 416) in an applying 430, resulting in the forming of an intermediate stack 435A. In some embodiments of the present disclosure, the applying 430 may be achieved in a roll-to-roll (R2R) process by directing a first continuous web (not shown) that includes the first composite structure 416 and a second continuous web (not shown) that includes the second composite structure 426 between two compressing rollers (not shown), such that the blocking layer 424 comes in direct contact with the first perovskite layer 412. The compressing rollers may provide sufficient force that the blocking layer 426 and the first perovskite layer 412 adhere to each other. In some embodiments of the present disclosure, an intermediate stack 435A resulting from the union of a first composite structure 416 with a second composite structure 426 may be subjected to a curing step 440 to provide, for example, improved adhesion of the two composite structures (416 and 426) to each other by releasing of the heat transfer tape or UV transfer tape via curing. For the example of a R2R process, in some embodiments of the present disclosure, compressing cylinders may be heated to accomplish the curing 440.

Referring again to FIG. 4A, once the two composite structures (416 and 426) having been successfully joined, a method 400 may then proceed with the removing 450 of the transfer layer 422 from the blocking layer 424, resulting in the forming of a second intermediate stack 435B constructed of a first perovskite layer 412 positioned between a blocking layer 424 and a substrate 414.

With the transfer layer 422 successfully removed from the blocking layer 424, a method 400 may then proceed with a second depositing 460 of a second perovskite layer 465 onto the blocking layer 424, resulting in the forming of the final device stack 470. As describe above for a first depositing 410 of a first perovskite layer 412, a second depositing 460 may be achieved using one or more vapor deposition methods (e.g., chemical vapor phase deposition) and/or liquid-phase deposition methods (e.g., blade-coating, curtain-coating, dip-coating, spin-coating, etc.). In some embodiments of the present disclosure, e.g., liquid-phase depositing, a second depositing 450 step may be followed by a treating step (not shown), e.g., heating a second perovskite layer 465, contacting a second perovskite layer 465 with a solvent, and/or contacting a second perovskite layer 465 with a gas stream. Among other things, such a treating step may assist a second perovskite layer 465 with reaching and/or approaching complete crystallization.

In some embodiments of the present disclosure, additional layers may be applied to a final device stack 470. For example, at least one of a contact layer and/or charge transport layer (not shown) may be deposited onto a final device stack 470, like the one illustrated in FIG. 4A. Further, although the exemplary method 400 described above is for a continuous process (e.g., R2R), one or more of the steps described above (depositing, preparing, applying, curing, removing, etc.) may be achieved in a batch and/or semi-batch process. In addition, some of the steps described may be performed in parallel and/or essentially simultaneously in a single step. For example, in some embodiments of the present disclosure, at least two of the applying 430, the curing 440, and/or the removing 450 may be performed in a single step or unit operation. Specifically, in some embodiments of the present disclosure, the applying 430 of a second composite layer 426 made of a heat release tape (an example of a transfer layer 422) and a blocking layer 424 to a surface of a first perovskite layer 412 of a first composite layer 416, may be achieved by placing the first composite layer 416 and the second composite layer 426 in a hot press, where the heat and pressure result in the curing 440 of heat release tape, thereby “releasing” the tape from underlying blocking layer 422, allowing the subsequent removing 450 of the tape from the blocking layer 422. In some embodiments of the present disclosure, such a process of transferring graphene to a perovskite layer may be achieved in manufacturing scale R2R processes using copper foil rolls in furnaces.

In one embodiment of the present disclosure, an SLG (i.e., a blocking layer 424) was grown on a copper foil, which was pressed onto a heat release transfer tape (e.g., transfer layer 422), thereby forming a second composite structure 426, as described above. Next, the copper foil was removed from the graphene blocking layer 424 and the transfer layer 422 (i.e., heat release transfer tape) by etching the copper foil in ammonium persulfate, leaving behind a single layer of graphene 424 positioned on the transfer layer 422. The SLG/heat transfer tape (i.e., second composite structure 426) was then applied (e.g., applying 430) to a first composite structure constructed of a CsPbBr₃ nanocrystal (NC) layer (first perovskite layer 412) positioned on a substrate 414 (e.g., glass and/or indium-doped tin oxide). The applying 430 was performed by a hot press (at exemplary conditions of 2000 kg of force at 130° C. for about 2 minutes), that both cured the transfer tape (i.e., transfer layer 422) and released the graphene blocking layer 424 from the transfer tape leaving the graphene blocking layer 424 positioned on the first perovskite layer 412. Thus, in this embodiment of the present disclosure, the applying 430, the curing 440, and the removing 445 steps were all performed in essentially a single step, whereby the applying of the first composite structure 416 to the second composite structure 426 results in the forming of a second intermediate stack 450B. (see FIG. 4A). Subsequently, a CsPbI₃ NC layer (e.g., second perovskite layer 465) was deposited by spin coating (e.g., second depositing 460) on top of the graphene blocking layer 424 to complete the CsPbI₃/SLG/CsPbBr₃ heterostructure (e.g., final device stack 470). Although the example provided relates to perovskite nanocrystals (e.g., crystals having a particles size less than 1000 nm), the methods and devices described herein may also apply to perovskites having other forms, for example, quantum dots (e.g., crystals having a particles size less than 7 nm), polycrystalline perovskites, and one or more films/layers of each.

The above deposition is agnostic to the perovskite composition. Films of CsPbBr₃ were convenient for investigations, but the composition can be any perovskite compositions described above. The graphene can be single layer, bilayer, or multi layer graphene deposited on top of the perovskite as seen fit. The graphene can be replaced with other 2D materials such as hexagonal boron nitride. The graphene transfer step, relying on heat transfer or UV-curing tape could be replaced with other graphene/2D materials stamping or transfer procedures, such as PDMS based stamping, solution deposition of the graphene, or other transfer techniques. For scaling up, the process could be done with R2R or stamping with larger area graphene.

Time of flight-secondary ion mass spectrometry (TOF-SIMS) measurements verified the retention of the separate halide ions across the two perovskite layers in the graphene layer-incorporated heterostructure. The CsPbI₃ layer remained isolated at the top of the film while the CsPbBr₃ layer remained at the bottom, with the graphene layer in-between (see Panel A of FIG. 4B). In contrast, the bromide and iodide anions rapidly mixed throughout the film in the control sample of CsPbBr₃/CsPbI₃ deposited without the graphene layer (see Panel B of FIG. 4B).

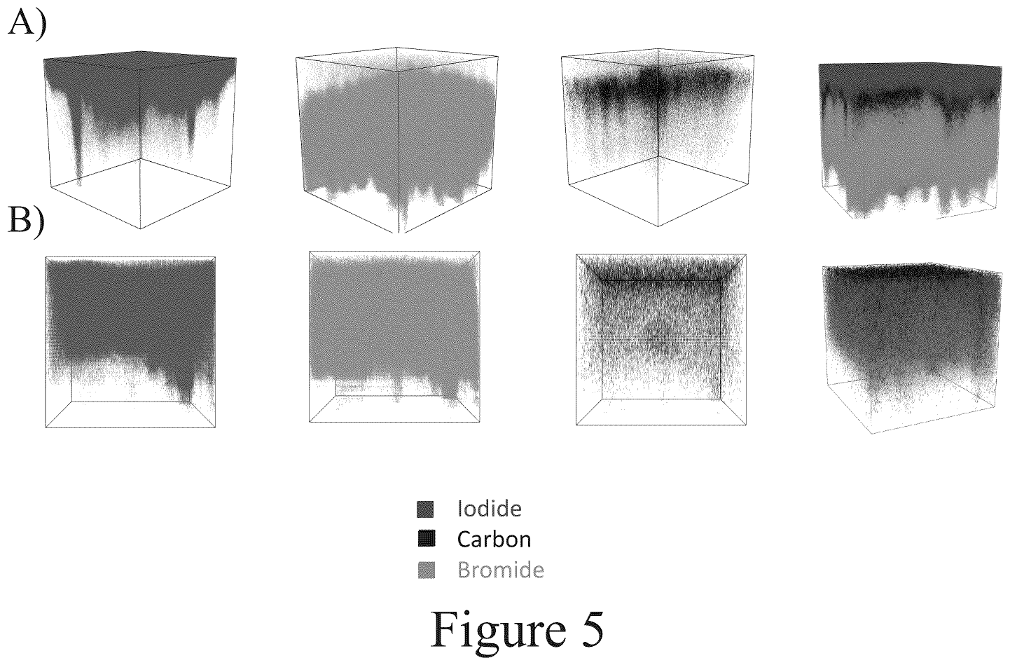

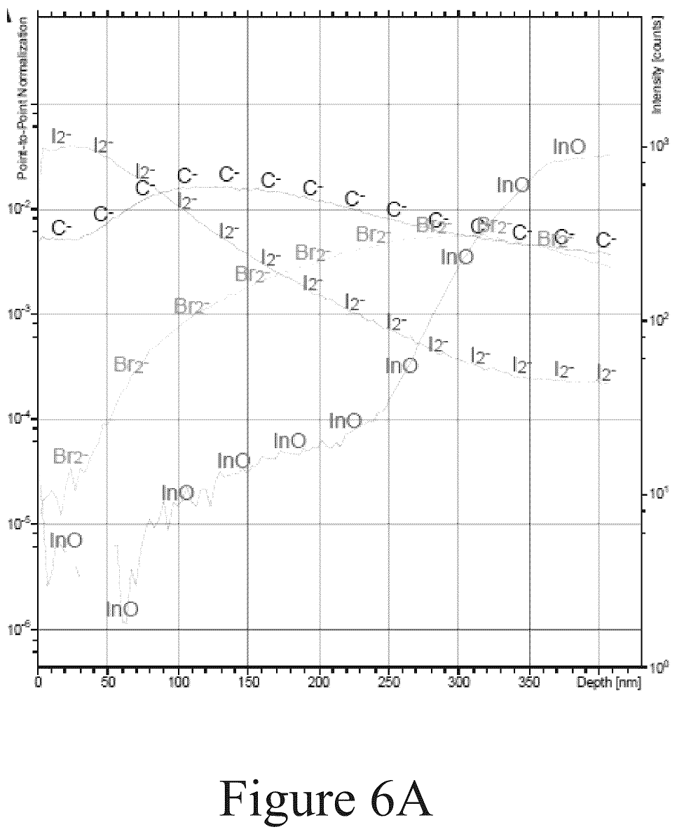

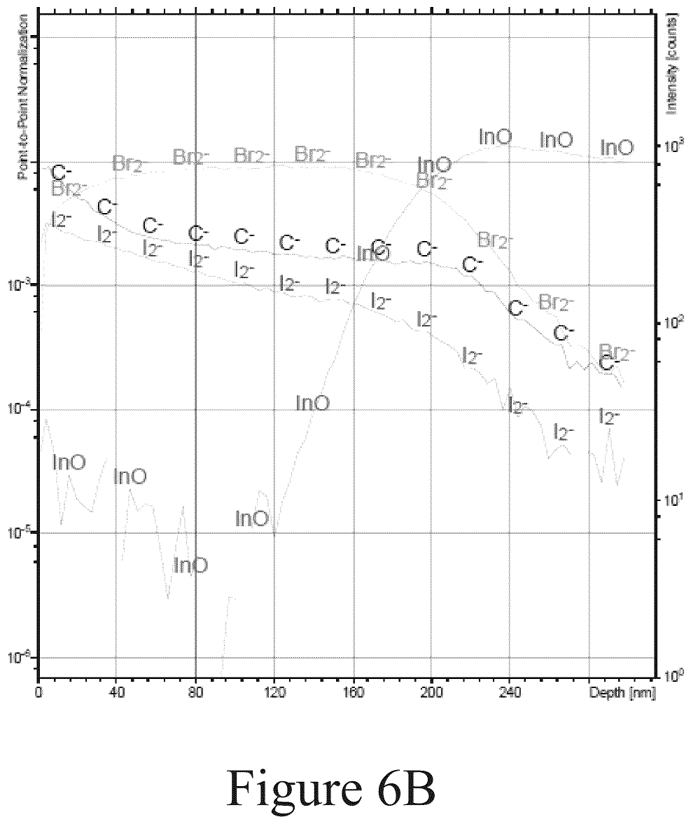

The top row (i.e., Panel A) of FIG. 5 shows the mass transfer occurring in the device having a graphene layer and the bottom row (i.e., Panel B) of FIG. 5 illustrates the mass transfer occurring in the control device constructed without an intervening graphene layer. In both panels of FIG. 5, diffusion is illustrated as follows from left to right: iodide, bromide, carbon, and a composite image of all three elements. Line profiles of the concentrations of these elements as a function of depth are illustrated in FIG. 6A (with a graphene layer) and 6B (without a graphene layer). (Note that FIGS. 6A and 6B report the amounts of Br²⁻, C⁻, and I²⁻ because these are the ions that form from sputtering Br⁻, C⁻, and I⁻ with the cesium ion beam that produces the TOF-SIMs data. The amounts are directly related to each other.)

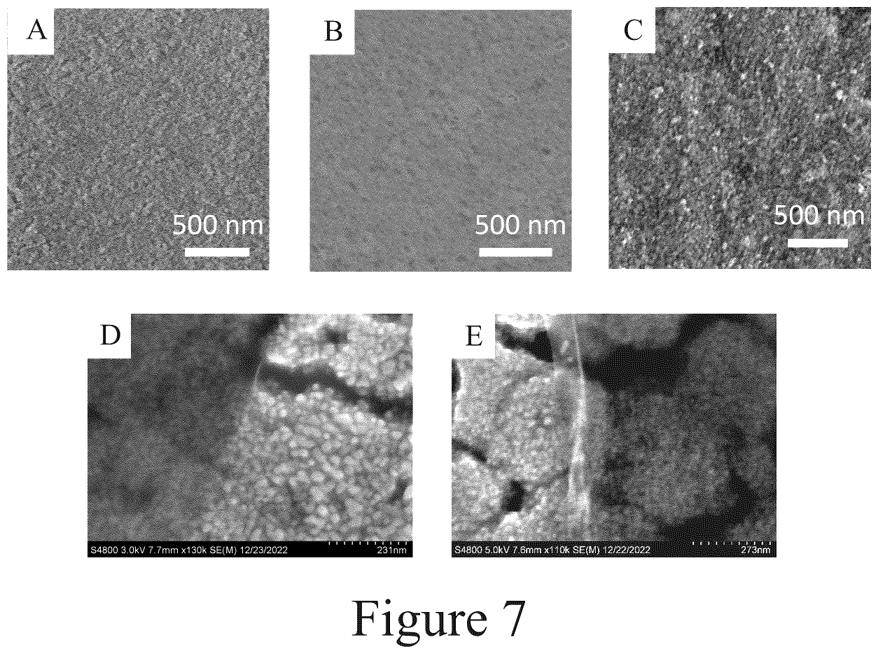

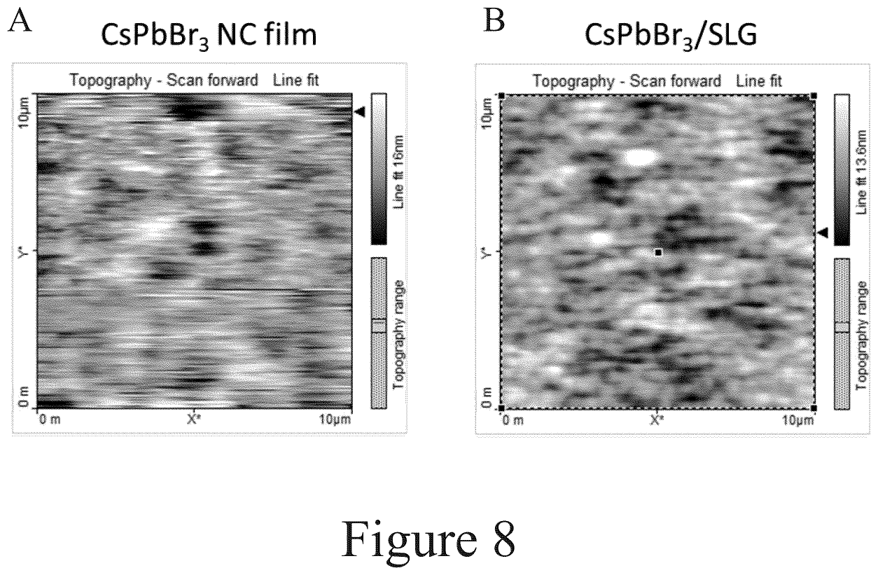

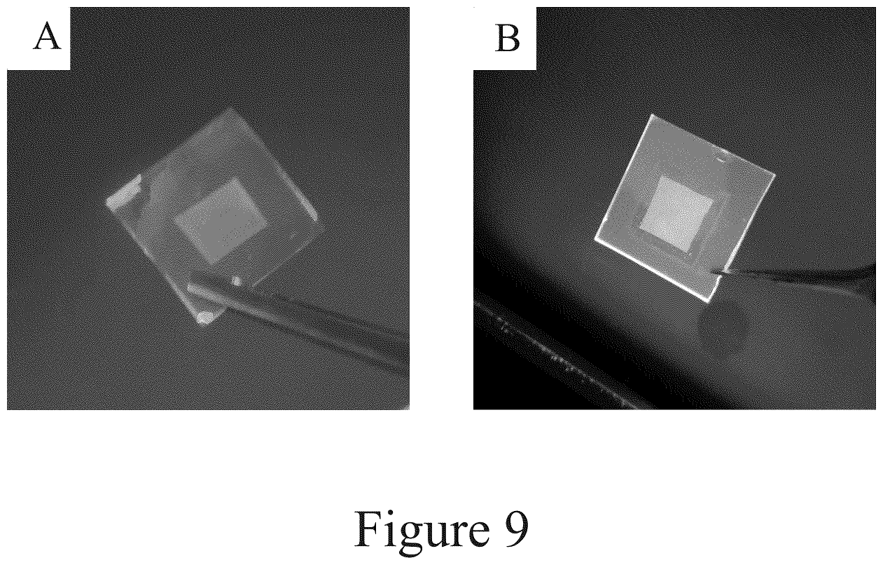

Cross sectional SEM (see Panel C of FIG. 4B) shows the heterostructure with the graphene layer has a sharp interface between the perovskite films. FIG. 7 shows the top view SEM images, FIG. 8 shows AFM topography, and FIG. 9 shows photographs of the heterostructure with the graphene layer and the control samples. FIG. 8, the topography maps, show the layer does not exhibit significant changes before or after the graphene, with local deviations only up to 16 nm which is about 1 to 2 nanocrystals thick. For the photographs, for both layers, the CsPbBr₃ was deposited onto the glass followed by scribing off material to provide a smaller region for the graphene transfer/consistency. Excess CsPb(Br₃₋ₓIₓ) is present at the edges of the substrate from incomplete scribing.

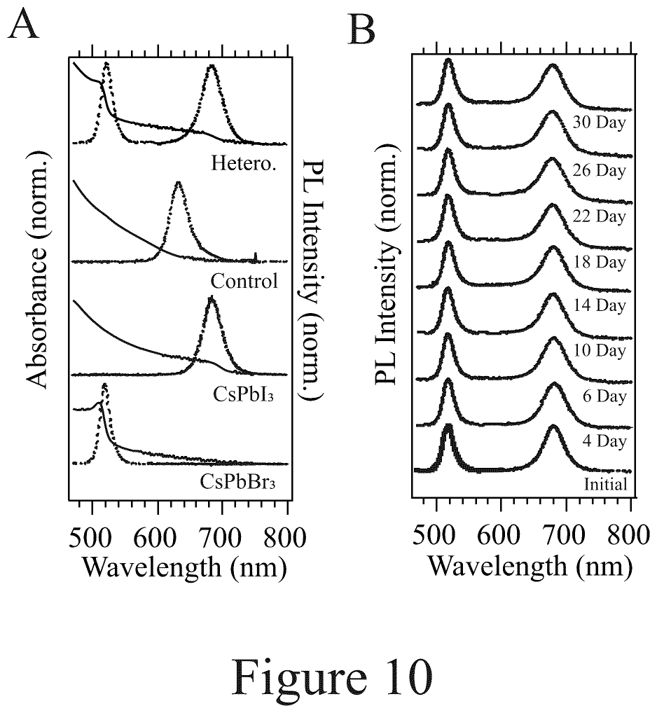

To further confirm that the graphene layer sufficiently blocks halide diffusion, UV-VIS absorbance and photoluminescence (PL) spectroscopy were utilized (see FIG. 10). A film of only CsPbBr₃ NCs shows an absorption onset and PL emission at 520 nm, while a film of only CsPbI₃ NCs shows an absorption onset and PL emission at 680 nm. When the NCs were deposited without a graphene layer as a control sample, the absorbance onset and PL emission rapidly merged and exhibited an absorption onset and PL at 630 nm, as expected when the halides mixed and formed CsPb(Br₃₋ₓIₓ). The halide mixing across the heterointerface was fast and was completed in the time scales required to transfer the samples for measurement (less than 30 minutes). In contrast, for the CsPbBr₃/SLG/CsPbI₃ heterostructure, discrete absorbance and PL features persisted and matched that of isolated samples. This is strong evidence that the heterostructure does not undergo halide diffusion across the graphene layer. Furthermore, the PL peaks in a heterostructure sample stored at ambient conditions over 30 days showed no clear evidence of shifting or change in the PL emission wavelengths (see Panel B of FIG. 10), demonstrating that the graphene layer successfully blocked ion diffusion over long time scales.

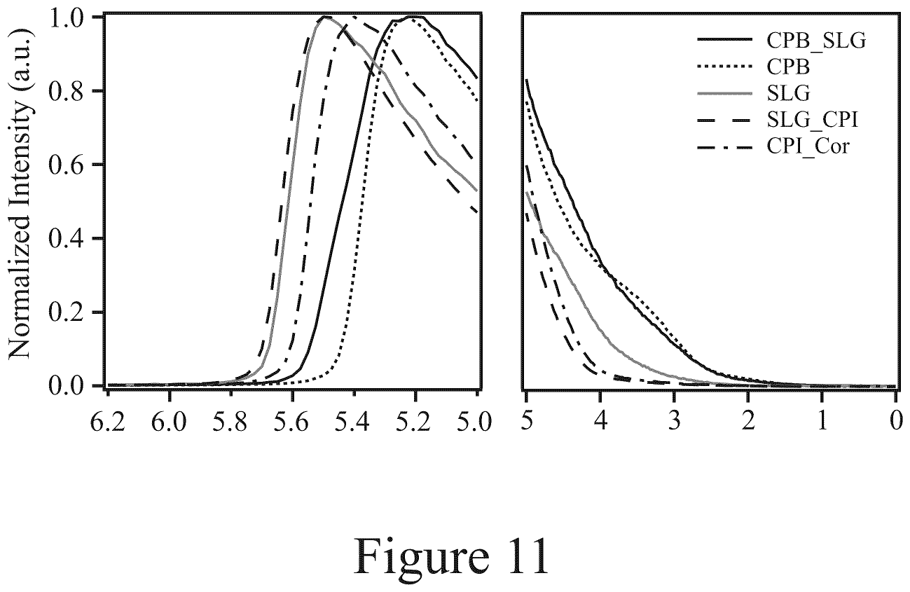

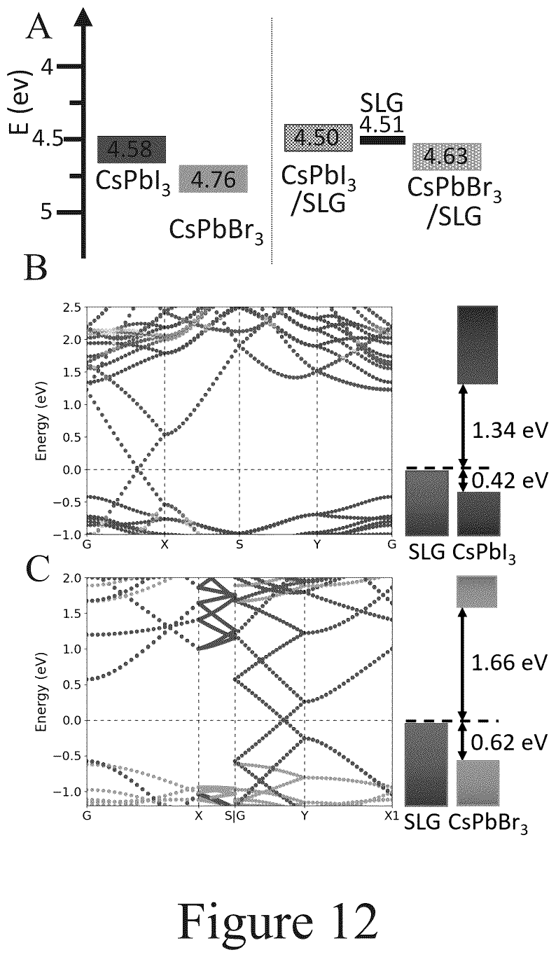

The electronic properties of the CsPbBr₃/SLG/CsPbI₃ heterostructure were investigated with ultraviolet photoelectron spectroscopy (UPS). The alignment of the work functions of the MHP films with and without a graphene layer (UPS spectra are shown in FIG. 11) indicate that incorporating a graphene layer slightly raises the work functions of the NC films for both CsPbI₃ and CsPbBr₃ in a similar fashion, about 0.08-0.13 eV (compare right and left sides of Panel A of FIG. 12). The measured work function of the graphene layer is slightly closer to vacuum than the VBs of both the CsPbI₃ and CsPbBr₃ (see Panel A of FIG. 12, left side).

Density functional theory (DFT) calculations corroborate what is observed in the UPS results. Using the FHI-aims code, (010) oriented slab supercells of CsPbI₃ and CsPbBr₃ interfaced with a graphene layer at the CsX-terminated surface were relaxed with the Perdew-Burke-Ernzerhof (PBE) semilocal density functional and a version of the Tkatchenko-Scheffler (TS) dispersion correction with a corrected van der Waals radius for Cs and 3×1×3 k-point grid (SLG/CsPbI₃ slab) and 1×1×1 k-point grid (SLG/CsPbBr₃ slab). Then the band structures were calculated with the hybrid HSE06 functional with spin-orbit coupling and with k4×4×4 (CsPbBr₃) k-point grids. To match the perovskite lattices to the PBE+TS optimized lattice parameter of a graphene layer (2.46 Å), the CsPbI₃ was strained by 2.34% normal and 4.28% shear strain, and the CsPbBr₃ was strained by 0.70% normal and 3.35% shear strain, with respect to the PBE+TS optimized relaxed perovskite lattices.

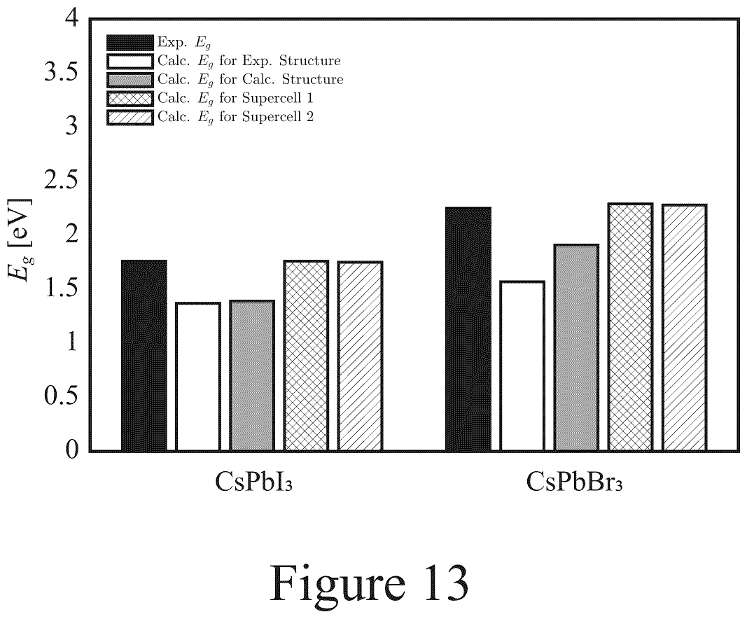

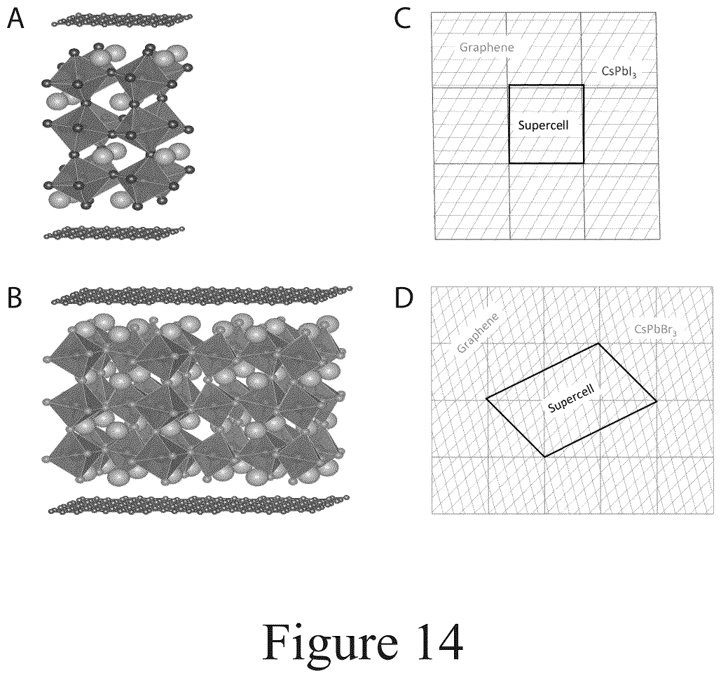

Calculations of two other supercells with different strain indicate this strain is negligible (see FIG. 13). FIG. 13 illustrates a comparison of experimental and calculated bandgaps for several structures, in particular the experimental bandgap determined through UPS and shown in FIGS. 6A and 6B the calculated bandgaps for the experimental bulk structures found in literature, the calculated bandgaps for relaxed bulk structures, and the calculated bandgaps for the supercells described in FIGS. 11 and 14. The results show that although the DFT calculations underestimate the bandgap for the bulk structures, the calculated bandgaps match the experimental bandgaps for all supercells. Because both supercell pairs match each other, it is concluded that the strain applied to these supercells does not affect the bandgap in a way that is qualitatively significant for the purposes of this work. The band structure calculations confirm a type I band alignment (see Panels B and C of FIG. 12). Furthermore, the Dirac point of a graphene layer falls inside the respective band gaps of the perovskites, and close to the VB, consistent with the work function extracted from UPS.

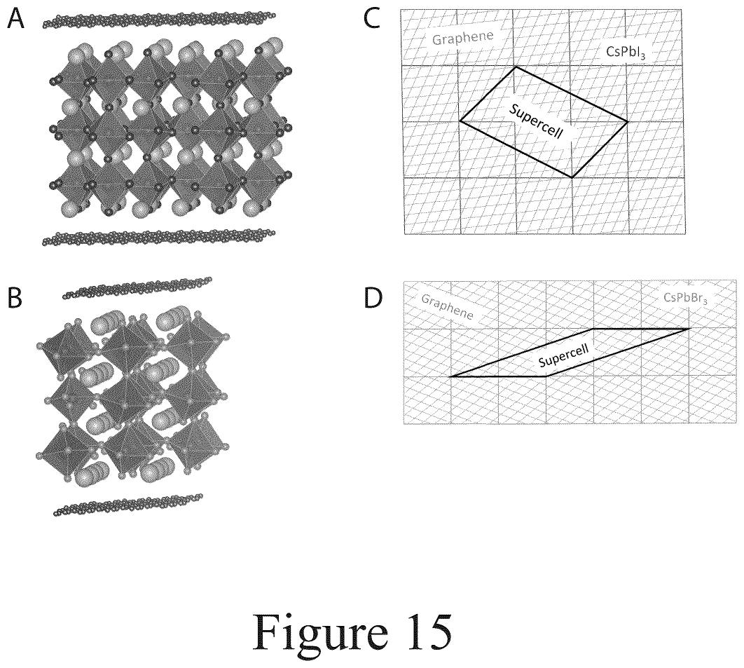

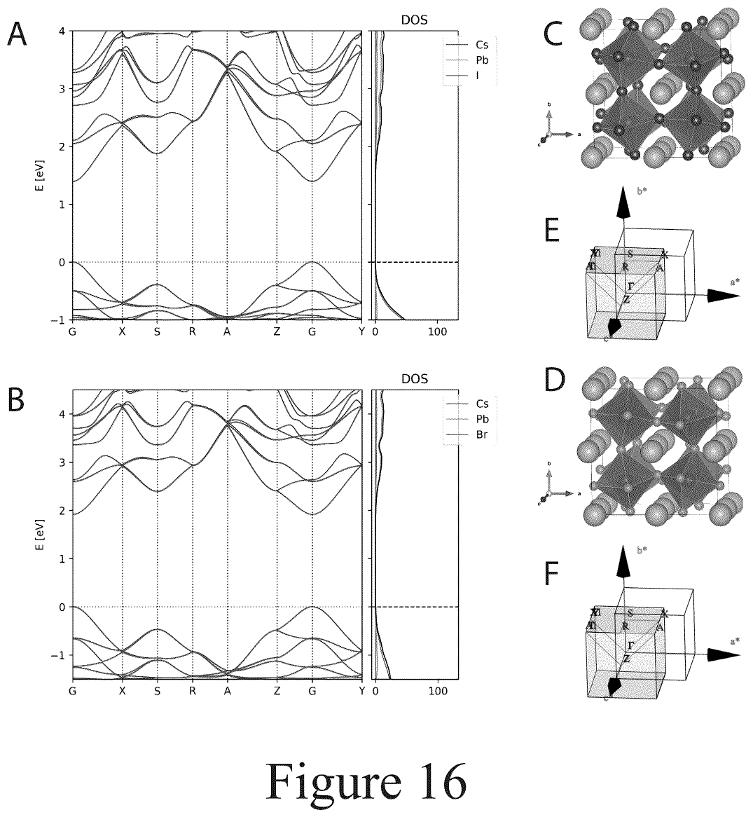

FIGS. 14 and 15 show the DFT relaxed models of the slab CsPbX₃/SLG structure, and FIG. 16 shows the band structures of the bulk CsPbX₃ without a graphene layer. Referring again to FIG. 14, the CsPbI₃ supercell was strained by 5.49% normal and 8.15° shear strain compared to the experimental bulk structure, or 2.34% normal and 4.28% shear strain compared to the relaxed bulk structure. The CsPbBr₃ supercell was strained by 3.64% normal and 3.30% shear strain compared to the experimental bulk structure, or 0.70% normal and 3.35% shear strain compared to the relaxed bulk structure. In both supercells, the graphene experiences 0.36% normal and 0° shear strain compared to the experimental lattice, and no strain compared to the relaxed lattice. To retain the characteristics of the bulk material between the sheets of graphene, the positions of the atoms in the middle octahedral layer (consisting of one PbX₂ plane and two CsX planes) were fixed during the supercell relaxation. The perovskites interface with the graphene on the (010) plane, using the convention where the longest lattice vector is in the b-direction. The perovskites supercells are terminated by the CsX-plane because experimental work suggests this termination is more likely. The PbX₂-terminated supercell was also simulated, and as expected, the band level alignment of the graphene within the perovskite bandgap did not match the UPS data as well as the CsX-terminated structure. All supercell and bulk relaxations were performed using PBE+TS with a corrected van der Waals radius for Cs, as implemented in FHI-aims all-electron code, with “intermediate” basis sets and numerical settings, and with 3×1×3 (CsPbI₃) and 2×1×2 (CsPbBr₃) k-point grids. To negate interaction between slabs, the graphene sheets were separated by 75 Å of vacuum and a dipole correction was employed in the [010] direction. In the relaxed geometries, the moduli of residual forces on the atoms and, where applicable, on lattice parameters were below 5·10⁻³ eV/A. For both supercells, the band structures were calculated using the hybrid Heyd-Scuseria-Ernzerhof (HSE06) functional with spin-orbit coupling with 4×4×4 k-point grids with the hybrid exchange-correlation coefficient set to 0.25 and a screening parameter of 0.11 (Bohr radii)⁻¹.

Referring again to FIG. 15, which illustrates second DFT relaxed slab structures with graphene and (Panel A) CsPbI₃ and (Panel B) CsPbBr₃ along with overhead views of the graphene/perovskite lattice combinations used to form the (Panel C) CsPbI₃ and (Panel D) CsPbBr₃ supercells, according to some embodiments of the present disclosure. All calculation parameters are the same as in FIG. 14 except the k-point grids (1×1×1 for the SLG/CsPbI₃ slab and 2×1×2 for the SLG/CsPbBr₃ slab) and the strain on each supercell. The CsPbI₃ supercell was strained by 0.80% normal and 6.17% shear strain compared to the experimental bulk structure, or −2.22% normal and 2.06% shear strain compared to the relaxed bulk structure. The CsPbBr₃ supercell was strained by 2.99% normal and 7.17% shear strain compared to the experimental bulk structure, or 0.07% normal and 7.12% shear strain compared to the relaxed bulk structure.

Referring again to FIG. 16, which illustrates DFT band structure and density of states for bulk (Panel A) CsPbI₃ and (Panel B) CsPbBr₃ along with corresponding unit cell (Panels C and E) and Brillouin zone showing the chosen k-path (Panels D and F), according to some embodiments of the present disclosure. Both structures were relaxed using the PBE+TS_alkali functional and 4×4×4 k-point grids with “tight” basis sets as implemented in FHI-aims and the convergence criterion set to 5E−3. The band structures were calculated with HSE06+SOC and 5×5×5 k-point grids with the hybrid exchange-correlation coefficient set to 0.25.

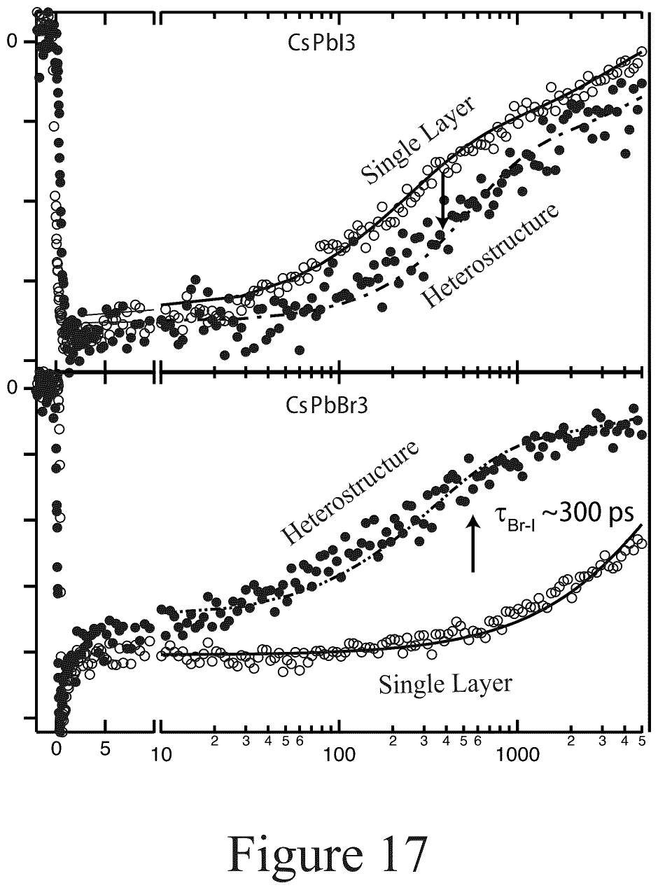

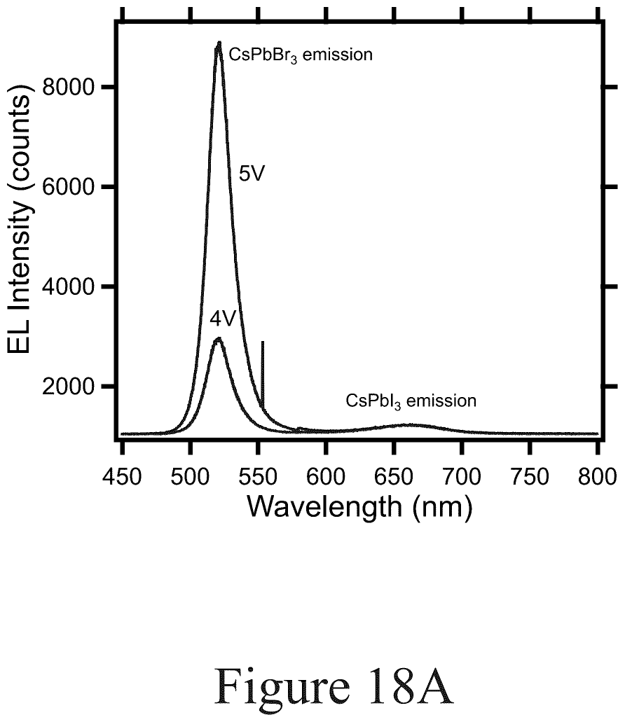

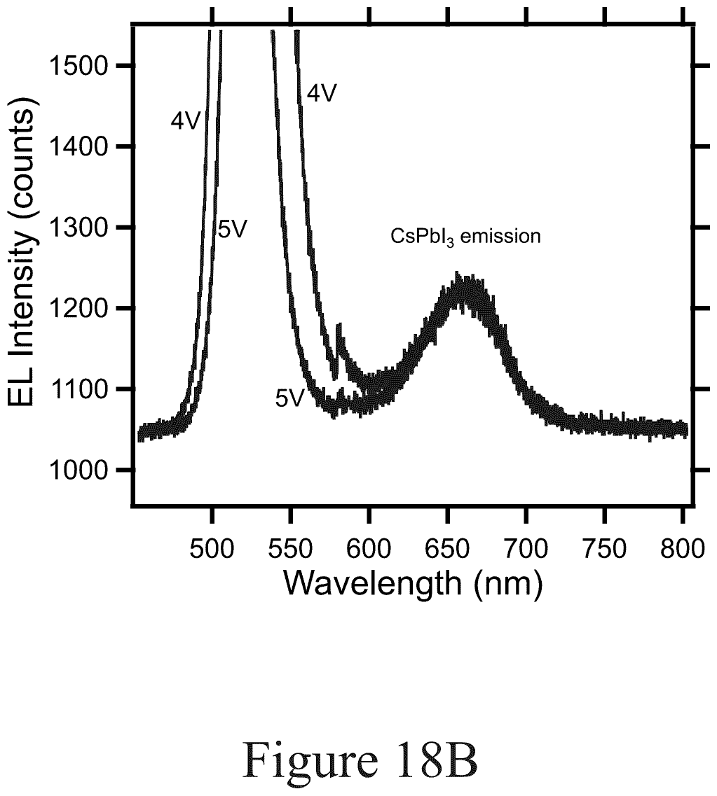

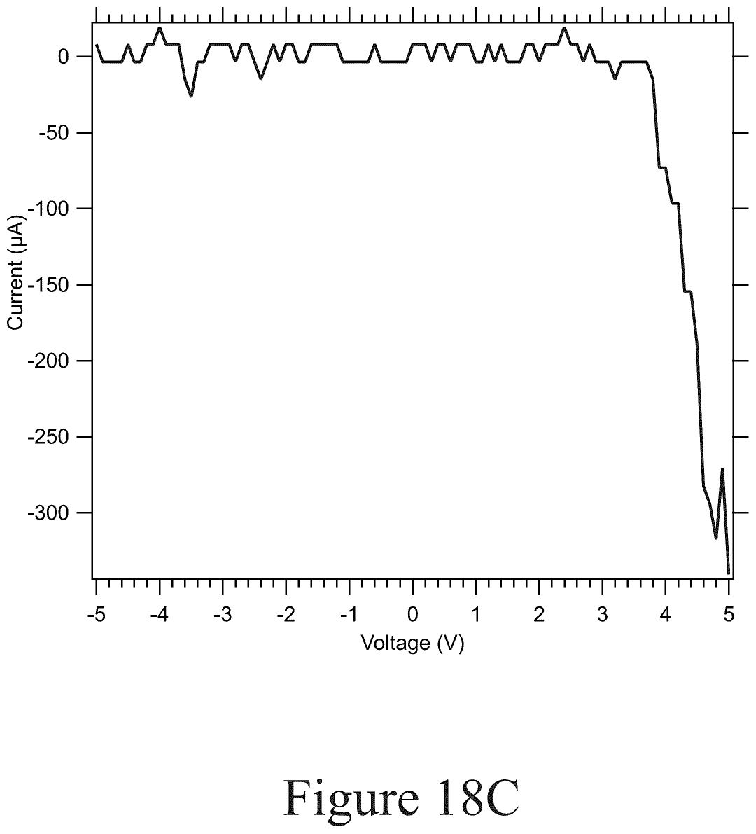

Transient absorbance spectroscopy (TAS) was used to probe the excited state dynamics of the heterostructure. Control experiments of individual CsPbI₃ (see Panel A of FIG. 14 red-open circles) and CsPbBr₃ (see bottom panel of FIG. 17, open circles) NC films integrated with a graphene layer characterize the decay of the excited state lifetime when carriers reside in the CsPbI₃ or CsPbBr₃. When integrated into the CsPbBr₃/SLG/CsPbI₃ heterostructure, carriers within the CsPbBr₃ decayed faster relative to the control (compare closed circles vs. open circles, bottom panel of FIG. 17). In contrast, carriers within the CsPbI₃ when incorporated into the heterostructure decay slower relative to the control CsPbI₃ (compare closed circles to open circles, see top panel of FIG. 17). The combination of the CsPbBr₃ exhibiting a faster decay of the ground state bleach while the CsPbI₃ decays slower, suggests that photogenerated carriers can easily be transferred from the CsPbBr₃ to the CsPbI₃. A simple transfer model was developed to explain the data (solid and dashed lines, both panels of FIG. 17). The decay rate within CsPbBr₃ and CsPbI₃ was characterized from the control experiments (solid lines, both panels of FIG. 17). Next, the slower decay in the CsPbI₃ and faster decay in the CsPbBr₃ was simultaneously modeled by incorporating transfer of carriers from the CsPbBr₃ to the CsPbI₃ (dashed lines, both panels of FIG. 17). The transfer time was found via non-linear least squares fitting to be ˜300 ps. The data suggest that the graphene layer does not act as a significant source of carrier recombination because the model of the TA experiment accounts for all photogenerated charge carriers either recombining or transferring from the CsPbBr₃ to CsPbI₃, i.e., no other decay channel was needed to model our data. In addition, one can conclude that both carriers are able to transfer in agreement with a type I band alignment because, in the case of only charge-transfer, one would expect the PL would quench in both films, which was not observed. Thus, TAS results demonstrates the graphene layer does not hinder the electronic communication in between the perovskite layers. To further probe, LEDs were fabricated with the CsPbBr₃/SLG/CsPbI₃ heterostructure. Stable electroluminescence was observed from both CsPbB₃ and CsPbI₃ (see FIGS. 18A-18C). The relatively low intensity of the CsPbI₃ emission is due to the processing conditions. The spin coated top layer of PFN-DOF significantly washes away the CsPbI₃ film, leaving small amount of material behind, likely a reason for the weak CsPbI₃ emission. (C) shows the I-V characteristics of the device in the dark. Due to processing conditions, the CsPbI₃ NC layer was kept thin and thus exhibited a weaker electroluminescence intensity relative to the CsPbBr₃. No mixing of the halides was observed, confirming that a graphene layer enables optoelectronic grade heterostructures.

### Materials and Methods

Single layer CVD grown graphene on both sides of copper foil (35 μm thick) was purchased from ACS Materials, where the manufacture determined grain size was ˜50 μm. Heat release tape was purchased from Semiconductor Equipment Corp. (21892-150MM, 9135 MS SS). Ammonium persulfate((NH₄)₂(SO₄)₂, 98%) cesium carbonate (Cs₂CO₃, 99%), lead iodide (PbI₂, 99.9985%), lead bromide (PbBr₂, 99.999%), hexane, octane, methylacetate, octadecene (90%), Oleic Acid (90%), oleylamine (90%), Poly(3,4-ethylenedioxythiophene)-poly(styrenesulfonate), 3.0-4.0% in H₂O, high-conductivity grad (PEDOT:PSS); and PFN-DOF, Mw>10,000; were purchased from Sigma Aldrich.

### Synthesis of CsPbX₃ Nanocrystals

CsPbX₃ nanocrystals (NCs) were prepared following a reported method.¹ In a three-necked round-bottom flask, 2.50 mmol (0.814 g) of Cs₂CO₃, 2.5 mL oleic acid (OA), and 40 mL of octadecene (ODE) were degassed under a vacuum at 120° C. for 1 hr followed by heating at 150° C. until completely clear and gas was no longer evolved in the flask. In a 250 mL three necked flask, 3.25 mmol of PbX₂ (1.50 mg PbI₂, 1.19 mg PbBr₂) in 40 mL ODE was degassed at 120° C. for 1 h under vacuum. Subsequently, 5 mL of oleic acid and 5 mL olelyamine were added to the reaction mixture. The temperature was then raised to 155° C. (CsPbI₃) or 170° C. (CsPbBr₃) followed by swift injection of 6.0 mL of the Cs-oleate precursor followed by immediately quenching the reaction with an ice bath. The NCs were then washed by adding 20 mL of dry methylacetate per 15 mL of reaction mixture followed by centrifuging at 8500 RPM for 5 min. The supernatant was discarded and the NCs were then redispersed in 15 mL of hexane per falcon tube (60 mL total) followed by centrifuging at 8000 RPM for 5 min. The supernatant was collected and stored overnight (˜18 hr) in −18° C. freezer to precipitate unreacted precursors. The precipitate was removed by centrifuging at 5000 RPM for 5 min and the supernatant was collected. The hexane was evaporated off under a stream of nitrogen and the NC solids were redispersed in 4 mL of octane total and diluted as needed.

### CsPbX₃ NC Films

All films were processed in a nitrogen glovebox. Glass or pre-patterned ITO substrates were sonicated in acetone then isopropanol for 10 min each, followed by a 15 min UV-Ozone treatment. NC solutions were filtered through a 0.22 μm syringe filter prior to use. The NC solution (30 μL) was deposited 3-5 s into 10 s spin cycle at 1000 rpm followed by 20s at 3000 rpm. The films were heated at 50° C. to remove octane and used for heterostructure fabrication.

### Graphene Preparation

Single layer graphene on copper foil was cut into pieces slightly larger than the substrate and pressed with 2000 kg of force onto heat release tape. The tape/graphene compound was then soaked in 0.3 M aqueous (NH₄)₂(SO₄)₂ for roughly 18 h to completely dissolve the copper foil followed by thoroughly rinsing with DI water and drying with N₂ gas.

### Heterostructure Fabrication

CsPbBr₃ NC films were prepared as previously described. Graphene was then pressed onto the NC film with 600 kg of force for two minutes with both the top and bottom plate of the press pre-heated to 130° C. When removed, the tape's adhesive was entirely cured and could be removed from the films effortlessly. CsPbI₃ NCs were then spin coated as previously described on top of the graphene. For long term PL studies, a thin film of PMMA was spin coated on top of the heterostructure to protect the CsPbI₃ from moisture. For TOF-SIMs measurements on the heterostructure, the CsPbBr₃ layer was deposited from a higher concentration to increase the thickness and improve the measurement quality.

### LED Fabrication

ITO substrates were sonicated in acetone then isopropanol for 10 min each, followed by a 15 min UV-Ozone treatment. In ambient atmosphere, PEDOT:PSS (3-4% in H₂O) was diluted 1:1 in DI H₂O then spin coated onto the substrate at 4000 RPM for 20 s, followed by annealing at 150° C. for 20 minutes. Subsequently, the heterostructure was deposited as described in “Heterostructure Fabrication”. After which, PFN-DOF (5 mg/mL in chlorobenzene) was deposited by spin coating at 4000 RPM for 20 s. Au was evaporated (100 nm) as a top contact. A note: the spin coated deposition of PFN-DOF significantly washed off the CsPbI₃ film, leaving small amounts of material behind.

### Absorbance and Photoluminescence (PL)

The absorbance spectra of the NC films and heterostructures were measured using ultraviolet-visible spectroscopy (Cary 6000i). PL spectra were acquired using a horiba spectrophotometer equipped with a 405 nm laser with a collection time of 2 s, 600 nm grating, and a slit width of 0.5 nm. PL spectra were collected from 450-605 nm without a cutoff filter and 605-800 nm with a 550 nm cutoff filter to avoid the laser frequency doubling line.

### Ultraviolet Photoluminescence Spectroscopy (UPS)

UPS was conducted in a PHI 5600 ultrahigh vacuum (UHV) system (˜5×10⁻¹⁰ mbar) with a hemispherical electron energy analyzer. UPS spectra were obtained with an Excitech H Lyman-α lamp (E-LUX™121) with an excitation energy of 10.2 eV and a pass energy of 5.85 eV. A sample bias of −5V was applied to samples during UPS measurements.

### Transient Absorbance Spectroscopy

The transient absorption spectroscopy was performed with a home-built set up on a Ti:Sapphire amplifer (Coherent Astrella, 800 nm, ˜60 fs pulse width, 1 kHz repetition rate). The output of the amplifier is split into two arms, one which pumps an optical parametric amplifier (Quantronix Palitra-Duo) and one which is used to generate white light continuum in a sapphire crystal. The probe is collected in an Ultrafast Systems Helios spectrometer. The pump wavelength used for all experiments was 450 nm with a pump energy of 16 nJ.

### Scanning Electron Microscopy (SEM)

The morphologies of the perovskite films and cross-sectional structures of the heterostructure were investigated using a Hitachi S-4800 scanning electron microscope.

### Time of Flight Secondary Ion Mass Spectrometry (TOF-SIMS)

An ION-TOF TOF-SIMS V Time of Flight SIMS (TOF-SIMS) spectrometer was utilized for depth profiling and chemical imaging of the perovskite utilizing methods covered in detail in previous reports.⁴ Analysis was completed utilizing a 3-lens 30 kV BiMn primary ion gun. High mass resolution depth profiles were completed with a 30 KeV Bi₃⁺ primary ion beam, (0.8 pA pulsed beam current), a 50×50 μm area was analyzed with a 128:128 primary beam raster. 3-D tomography and high-resolution imaging was completed with a 30 KeV Bi₃⁺⁺ primary ion beam, (0.1 pA pulsed beam current), a 25×25 μm area was analyzed with a 512:512 primary beam raster. Sputter depth profiling was accomplished with 1 kV Cesium ion beam (6.5 nA sputter current) with a raster of 200×200 microns.

### EXAMPLES

Example 1. A device comprising: a first layer comprising a first perovskite comprising a first cation (A), a second cation (B), and first anion (X); a second layer comprising a second perovskite comprising a third cation (A′), a fourth cation (B′), and a second anion (X′), and a third layer comprising a two-dimensional (2D) material, wherein: the third layer is physically positioned between the first layer and the second layer, and the third layer minimizes or eliminates the transfer of at least one of A, A′, B, B′, X, or X′ between the first layer and the second layer.

Example 2. The device of Example 1, wherein the 2D material comprises at least one of graphene or hexagonal boron nitride, phosphorene, silicene, or a transition metal dichalcogenide.

Example 3. The device of either Example 1 or Example 2, wherein the transition metal dichalcogenide comprises at least one of MoS₂, MoSe₂, MoTe₂, WS₂, or WSe₂.

Example 4. The device of any one of Examples 1-3, wherein the third layer is a monolayer of the 2D material.

Example 5. The device of any one of Examples 1-4, wherein the first perovskite comprises at least one of a one-dimensional (1D) structure, a 2D structure, or a three-dimensional (3D) structure.

Example 6. The device of any one of Examples 1-5, wherein each of A and A′ independently comprise at least one of methylammonium (MA), formamidinium (FA), dimethylammonium (DMA), ethylammonium, acetamidinium, guanidinium, methylenediammonium, propylammonium, butylammonium, octylammonium, dodecylammonium, phenethylammonium, or cesium.

Example 7. The device of any one of Examples 1-6, wherein each of A and A′ independently comprise at least one of methylammonium (MA), formamidinium (FA), dimethylammonium (DMA), or cesium.

Example 8. The device of any one of Examples 1-7, wherein at least a portion of A of the first perovskite is different than A′ of the second perovskite.

Example 9. The device of any one of Examples 1-8, wherein the third layer minimizes the transfer of at least one of A or A′ from the first layer to the second layer or the transfer of at least one of A or A′ from the second layer to the first layer.

Example 10. The device of any one of Examples 1-9, wherein: the first perovskite comprises FABX₃, and the second perovskite comprises CsB′X′₃.

Example 11. The device of any one of Examples 1-10, wherein the third layer minimizes the transfer of at least one of FA or MA from the first layer to the second layer or the transfer of at least one of Cs or DMA from the second layer to the first layer.

Example 12. The device of any one of Examples 1-11, wherein: at least a portion of A of the first perovskite is the same as A′ of the second perovskite, and A is present in the first perovskite at a first stoichiometry that is different than a second stoichiometry of A′ in the second perovskite.

Example 13. The device of any one of Examples 1-12, wherein the third layer minimizes the transfer of at least one of A or A′ from the first layer to the second layer or the transfer of at least one of A or A′ from the second layer to the first layer.

Example 14. The device of any one of Examples 1-132, wherein: the first perovskite comprises Cs₁₋ₓFAₓBX₃, the second perovskite comprises Cs_{1-y}FA_{y}B′X′₃, 0<x<1, 0<y<1, and y≠x.

Example 15. The device of any one of Examples 1-14, wherein the third layer minimizes the transfer of at least one of Cs or FA from the first layer to the second layer or the transfer of at least one of Cs or FA from the second layer to the first layer.

Example 16. The device of any one of Examples 1-15, wherein each of B and B′ independently comprise at least one of a 2+ cation or a 3+ cation.

Example 17. The device of any one of Examples 1-16, wherein each of B and B′ independently comprise at least one of tin, lead, germanium, manganese, bismuth, silver, antimony, indium, copper, or europium.

Example 18. The device of any one of Examples 1-17, each of B and B′ independently comprise at least one of tin or lead.

Example 19. The device of any one of Examples 1-18, wherein at least a portion of B of the first perovskite is different than B′ of the second perovskite.

Example 20. The device of any one of Examples 1-19, wherein the third layer minimizes the transfer of at least one of B or B′ from the first layer to the second layer or the transfer of at least one of B or B′ from the second layer to the first layer.

Example 21. The device of any one of Examples 1-20, wherein: the first perovskite comprises APbX₃, and the second perovskite comprises A′SnX′₃.

Example 22. The device of any one of Examples 1-21, wherein the third layer minimizes the transfer of at least one of Pb from the first layer to the second layer or the transfer of Sn from the second layer to the first layer.

Example 23. The device of any one of Examples 1-22, wherein: at least a portion of B of the first perovskite is the same as B′ of the second perovskite, and B is present in the first perovskite at a first stoichiometry that is different than a second stoichiometry of B′ in the second perovskite.

Example 24. The device of any one of Examples 1-23, wherein the third layer minimizes the transfer of at least one of B or B′ from the first layer to the second layer or the transfer of at least one of B or B′ from the second layer to the first layer.

Example 25. The device of any one of Examples 1-24, wherein: the first perovskite comprises APb₁₋ₐSnₐX₃, the second perovskite comprises A′Pb_{1-b}Sn_{b}X′₃, 0<a<1, 0<b<1, and b≠a.

Example 26. The device of any one of Examples 1-25, wherein the third layer minimizes the transfer of at least one of Pb or Sn from the first layer to the second layer or the transfer of at least one of Pb or Sn from the second layer to the first layer.

Example 27. The device of any one of Examples 1-26, wherein each of X and X′ independently comprise at least one of a halide, acetate, or a pseudohalide.

Example 28. The device of any one of Examples 1-27, wherein the pseudohalide comprises at least one of cyanide, cyaphide, isocyanide, hydroxide bioxide, hydrosulfide bisulfide, cyanate, isocyanate, fulminate, thiocyanate, isothiocyanate, hypothiocyanite, nitrite, tetracarbonylcobalt, trinitromethanide, or tricyanomethanide.

Example 29. The device of any one of Examples 1-28, wherein each of X and X′ independently comprise at least one of fluoride, iodide, chloride, or bromide.

Example 30. The device of any one of Examples 1-29, wherein at least a portion of X of the first perovskite is different than X′ of the second perovskite.

Example 31. The device of any one of Examples 1-30, wherein the third layer minimizes the transfer of at least one of X or X′ from the first layer to the second layer or the transfer of at least one of X or X′ from the second layer to the first layer.

Example 32. The device of any one of Examples 1-31, wherein: the first perovskite comprises ABI₃, and the second perovskite comprises A′B′Br₃.

Example 33. The device of any one of Examples 1-32, wherein the third layer minimizes the transfer of at least one of iodide from the first layer to the second layer or the transfer of bromide from the second layer to the first layer.

Example 34. The device of any one of Examples 1-33, wherein: at least a portion of X of the first perovskite is the same as X′ of the second perovskite, and X is present in the first perovskite at a first stoichiometry that is different than a second stoichiometry of X′ in the second perovskite.

Example 35. The device of any one of Examples 1-34, wherein the third layer minimizes the transfer of at least one of X or X′ from the first layer to the second layer or the transfer of at least one of X or X′ from the second layer to the first layer.

Example 36. The device of any one of Examples 1-35, wherein: the first perovskite comprises AB(I₁₋ᵥBrᵥ)₃, the second perovskite comprises A′B′(I_{1-w}Br_{w})₃, 0<v<1, 0<w<1, and w≠v.

Example 37. The device of any one of Examples 1-36, wherein the third layer minimizes the transfer of at least one of iodide or bromide from the first layer to the second layer or the transfer of at least one of iodide or bromide from the second layer to the first layer.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein.

Thus, the following claims are hereby incorporated into this Detailed Description, with each claim standing on its own as a separate aspect, embodiment, or configuration.

What is claimed is:

1. A device comprising:
a first layer comprising a first perovskite comprising a first cation (A), a second cation (B), and first anion (X);
a second layer comprising a second perovskite comprising a third cation (A′), a fourth cation (B′), and a second anion (X′); and
a third layer comprising a two-dimensional (2D) material, wherein:
the third layer is physically positioned between the first layer and the second layer, and
the third layer minimizes or eliminates the transfer of at least one of A, A′, B, B′, X, or X′ between the first layer and the second layer.

2. The device of claim 1, wherein the 2D material comprises at least one of graphene or hexagonal boron nitride, phosphorene, silicene, or a transition metal dichalcogenide.

3. The device of claim 2, wherein the transition metal dichalcogenide comprises at least one of MoS₂, MoSe₂, MoTe₂, WS₂, or WSe₂.

4. The device of claim 1, wherein the third layer is a monolayer of the 2D material.

5. The device of claim 1, wherein the first perovskite comprises at least one of a one-dimensional (1D) structure, a 2D structure, or a three-dimensional (3D) structure.

6. The device of claim 1, wherein each of A and A′ independently comprise at least one of methylammonium (MA), formamidinium (FA), dimethylammonium (DMA), ethylammonium, acetamidinium, guanidinium, methylenediammonium, propylammonium, butylammonium, octylammonium, dodecylammonium, phenethylammonium, or cesium.

7. The device of claim 6, wherein the third layer minimizes the transfer of at least one of A or A′ from the first layer to the second layer or the transfer of at least one of A or A′ from the second layer to the first layer.

8. The device of claim 1, wherein each of B and B′ independently comprise at least one of a 2+ cation or a 3+ cation.

9. The device of claim 8, wherein each of B and B′ independently comprise at least one of tin, lead, germanium, manganese, bismuth, silver, antimony, indium, copper, or europium.

10. The device of claim 9, wherein the third layer minimizes the transfer of at least one of B or B′ from the first layer to the second layer or the transfer of at least one of B or B′ from the second layer to the first layer.

11. The device of claim 1, wherein each of X and X′ independently comprise at least one of a halide, acetate, or a pseudohalide.

12. The device of claim 11, wherein the pseudohalide comprises at least one of cyanide, cyaphide, isocyanide, hydroxide bioxide, hydrosulfide bisulfide, cyanate, isocyanate, fulminate, thiocyanate, isothiocyanate, hypothiocyanite, nitrite, tetracarbonylcobalt, trinitromethanide, or tricyanomethanide.

13. The device of claim 11, wherein the halide comprises at least one of fluoride, iodide, chloride, or bromide.

14. The device of claim 1, wherein at least a portion of X of the first perovskite is different than X′ of the second perovskite.

15. The device of claim 14, wherein the third layer minimizes the transfer of at least one of X or X′ from the first layer to the second layer or the transfer of at least one of X or X′ from the second layer to the first layer.

16. The device of claim 14, wherein:
the first perovskite comprises ABI₃, and
the second perovskite comprises A′B′Br₃.

17. The device of claim 16, wherein the third layer minimizes the transfer of at least one of iodide from the first layer to the second layer or the transfer of bromide from the second layer to the first layer.

18. The device of claim 13, wherein:
at least a portion of X of the first perovskite is the same as X′ of the second perovskite, and
X is present in the first perovskite at a first stoichiometry that is different than a second stoichiometry of X′ in the second perovskite.

19. The device of claim 18, wherein the third layer minimizes the transfer of at least one of X or X′ from the first layer to the second layer or the transfer of at least one of X or X′ from the second layer to the first layer.

20. The device of claim 18, wherein:
the first perovskite comprises AB(I₁₋ᵥBrᵥ)₃,
the second perovskite comprises A′B′(I_{1-w}Br_{w})₃,
0<v<1, 0<w<1, and w≠v.

21. The device of claim 20, wherein the third layer minimizes the transfer of at least one of iodide or bromide from the first layer to the second layer or the transfer of at least one of iodide or bromide from the second layer to the first layer.
